(19) United States
(12) Patent Application Publication
(10) Pub. No.: US 2022/0325398 A1
(43) Pub. Date: Oct. 13, 2022

(54) Method Of Forming A Halide-Containing Perovskite Film

(71) Applicant: Applied Materials, Inc., Santa Clara, CA (US)

(72) Inventors: Vijay Bhan Sharma, Rajasthan (IN); Abhijeet Laxman Sangle, Maharashtra (IN); Ankur Anant Kadam, Thane (IN); Suresh Chand Seth, Mumbai (IN); Richa Pandey, Kanpur (IN); Dinesh Kabra, Mumbai (IN); Valipe Ramgopal Rao, New Delhi (IN)

(73) Assignee: Applied Materials, Inc., Santa Clara, CA (US)

(21) Appl. No.: 17/229,492

(22) Filed: Apr. 13, 2021

(51) Int. Cl. C23C 14/06; C23C 14/02; C23C 14/24; C23C 14/54; C23C 14/58; B05D 1/00; B05D 3/00

(52) U.S. Cl. CPC C23C 14/0694; C23C 14/024; C23C 14/24; C23C 14/54; C23C 14/5806; B05D 1/005; B05D 3/007; B05D 2401/10; B05D 2425/02

(57) ABSTRACT

A hybrid halide perovskite film and methods of forming a hybrid halide perovskite film on a substrate are described. The film is formed on the substrate by depositing an organic solution on a substrate, heating the substrate and the organic solution to form an organic layer on the substrate, depositing an inorganic layer on the organic layer, and heating the substrate having the inorganic layer thereon to form a hybrid halide perovskite film. In some embodiments, the hybrid halide perovskite film comprises a CH[NH₂]₂⁺MX₃ compound, where M is selected from the group consisting of Sn, Pb, Bi, Mg and Mn, and where X is selected from the group consisting of I, Br and Cl. In other embodiments, the hybrid halide perovskite film comprises a FAMX₃ compound. Methods of forming a piezoelectric device are also disclosed.

### TECHNICAL FIELD

Embodiments of the present disclosure pertain to films and piezoelectric devices. More particularly, embodiments of the disclosure provide methods of forming hybrid halide perovskite films and methods of forming piezoelectric devices.

### BACKGROUND

Organic and inorganic portions of organic-inorganic hybrid halide thin films are typically combined in solution phase and then spin-coated, followed by solvent evaporation. Conventional techniques of forming these films, such as spin-coating, may lead to formation of pin-holes and voids in the films due to evaporation of solvent. Using these techniques, the deposited film is not formed in a single phase, as double perovskite is formed in the solution phase.

Hybrid halide thin films are often used in the manufacture of piezoelectric materials and devices. Piezoelectric ceramics are used in various fields of technology, including use as a material for filters, actuators, transducers and any other devices capable of converting an electric energy (electric signal) directly into a mechanical energy (mechanical signal).

Lead-containing perovskite compounds are commonly used piezoelectric ceramic materials, including lead zinc titanate (PZT), as an example. PZT has environmental pollution implications caused by its manufacture and disposal of such PZT-containing devices. Lead contained in PZT, including lead oxide (PbO), in particular, is harmful.

Generally, lead-free piezoelectric materials are inferior in terms of electromechanical coupling factor and mechanical quality factor, as compared to lead-containing piezoelectric materials. Usually, lead-based piezoelectric ceramic materials cannot be easily sintered, so formation of, for example, lead zirconate titanate (“PZT”), requires a hot-pressing process, which is disadvantageous in the cost and efficiency of device manufacture, and in the freedom of design of the configuration and size of device structure.

Of the lead-free piezoelectric materials, formamidinium tin iodide, for example, has comparative piezoelectric properties to lead-containing piezoelectric materials. Additionally, lead-reduced or lead-free piezoelectric materials have exhibited properties including long carrier diffusion lengths (>100 μm), tunable bandgaps (1.45-2.4 eV), and high absorption coefficients (>105 cm⁻¹). The low annealing temperature of lead-free piezoelectric materials, such as formamidinium tin iodide (FASnI₃), may not require as high sintering temperatures as lead-containing piezoelectric materials.

Accordingly, there is a need for methods of forming lead-free organic-inorganic hybrid halide films and methods of forming a piezoelectric device comprising such films.

### SUMMARY

One or more embodiments of the disclosure are directed to a method of forming a film comprising depositing a CH[NH₂]₂X solution on a substrate, where X is selected from the group consisting of I, Br and Cl, heating the substrate and the CH[NH₂]₂X solution to form a CH[NH₂]₂X layer on the substrate, depositing an MX₂ layer, where M is selected from the group consisting of Sn, Pb, Bi, Mg and Mn on the CH[NH₂]₂X layer and heating the substrate having the CH[NH₂]₂X layer and the MX₂ layer thereon to form a hybrid halide perovskite film comprising a CH[NH₂]₂⁺MX₃ compound.

Other embodiments of the disclosure are directed to a method of forming a film comprising depositing a formamidinium halide (FAX) solution, where X is selected from the group consisting of I, Br and Cl on a substrate, heating the substrate and the FAX solution to form a FAX layer on the substrate, depositing an MX₂ layer, where M is selected from the group consisting of Sn, Pb, Bi, Mg and Mn on the FAX layer, and heating the substrate having the FAX layer and the MX₂ layer thereon to form a hybrid halide perovskite film comprising a FAMX₃ compound.

Further embodiments of the disclosure are directed to a method of forming a piezoelectric device comprising depositing a formamidinium halide (FAX) solution, where X is selected from the group consisting of I, Br and Cl, and a polymeric material to produce a mixture, coating the mixture on a substrate, heating the substrate and the mixture to form a FAX layer on the substrate, depositing an MX₂ layer where M is selected from the group consisting of Sn, Pb, Bi, Mg and Mn on the FAX layer, and heating the substrate having the FAX layer and the MX₂ layer thereon to produce a piezoelectric film comprising a FAMX₃ compound disposed on the substrate.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments. The embodiments as described herein are illustrated by way of example and not limitation in the figures of the accompanying drawings in which like references indicate similar elements.

FIG. 1 illustrates a flow diagram of a method of forming a film according to one or more embodiments;

FIG. 2 illustrates a flow diagram of a method of forming a piezoelectric device according to one or more embodiments;

FIG. 3 illustrates a schematic cross-sectional view of a hybrid halide perovskite film according to one or more embodiments; and

FIG. 4 illustrates an x-ray diffraction (XRD) reading of a formamidinium tin iodide (FASnI₃) film according to one or more embodiments.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” may encompass both an orientation of above and below. The device may be otherwise oriented (rotated 90 degrees or at other orientations) and the spatially relative descriptors used herein interpreted accordingly.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. In one or more embodiments, the particular features, structures, materials, or characteristics are combined in any suitable manner.

A “substrate” as used herein, refers to any substrate or material surface formed on a substrate upon which film processing is performed during a fabrication process. For example, a substrate surface on which processing can be performed includes materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application.

Substrates include, without limitation, semiconductor wafers. Substrates may be exposed to a pretreatment process to polish, etch, reduce, oxidize, hydroxylate, anneal and/or bake the substrate surface. In addition to film processing directly on the surface of the substrate itself, in the present disclosure, any of the film processing steps disclosed may also be performed on an under-layer formed on the substrate as disclosed in more detail below, and the term “substrate surface” is intended to include such under-layer as the context indicates. For example, where a film/layer or partial film/layer has been deposited onto a substrate surface, the exposed surface of the newly deposited film/layer becomes the substrate surface.

The substrate may be any substrate capable of having material deposited thereon, such as a silicon substrate, a III-V compound substrate, a silicon germanium (SiGe) substrate, an epi-substrate, a silicon-on-insulator (SOI) substrate, a display substrate such as a liquid crystal display (LCD), a plasma display, an electro luminescence (EL) lamp display, a solar array, solar panel, a light emitting diode (LED) substrate, a semiconductor wafer, or the like. In some embodiments, one or more additional layers may be disposed on the substrate. For example, in some embodiments, a layer comprising a metal, a nitride, an oxide, or the like, or combinations thereof may be disposed on the substrate. In one or more embodiments, the substrate comprises silicon (Si) or poly-silicon (p-Si). In some embodiments, the substrate comprises a poly-Silicon substrate. In some embodiments, the substrate is chemically and/or physically unmodified.

As used herein, the term “halide” refers to a material, of which one part is a halogen atom and another part is an element or radical that is less electronegative than the halogen, to make a fluoride, chloride, bromide, or iodide compound. A halide ion is a halogen atom bearing a negative charge. As known to those of skill in the art, a halide anion includes fluoride (F—), chloride (Cl—), bromide (Br—), and iodide (I—).

As used herein, the term “spin-coat” or “spin-coating” refers to a procedure used to deposit uniform films onto substrates. Typically, a small amount of coating material is applied on the center of the substrate, which is either spinning at low speed or not spinning at all. The substrate is then rotated at a speed of up to 10,000 rpm to spread the coating material by centrifugal force.

As used herein, the term “thermal evaporation” refers to a physical vapor deposition (PVD) technique using a resistive heat source to evaporate a solid material in a vacuum environment to form a film. Thermal evaporation techniques include different methods that can be applied to heat the material. One method is resistance heat evaporation wherein the material is heated until fusion by means of an electrical current. The electrical current passes through a filament or metal plate (evaporator) where the target material is deposited. The vaporized material is then deposited on the substrate.

Another thermal evaporation technique is electron beam evaporation where high energy electron beam bombardment onto the target material produces heat energy. The electron beam is generated by an electron gun. The electron gun uses thermionic emission of electrons produced by an incandescent filament. Thermionic emission is the process by which free electrons are emitted from the surface of a metal when external heat energy is applied. Emitted electrons are accelerated by a high voltage potential (kilovolts). A magnetic field may be applied to bend the electron trajectory. Bending the electron trajectory allows the electron gun to be positioned below the evaporation line. As electrons can be focalized, it is possible to obtain localized heating on the material to evaporate, with a high density of evaporation power. Localized heating on the material to evaporate enables control of the evaporation rate.

Effusion cell based thermal evaporation is a thermal evaporation technique of an effusion cell. As used herein, the term “effusion cell” refers to low temperature effusion cells (LTEC), standard effusion cells (MTEC), high temperature effusion cells (HTEZ/HTS), production effusion cells (PEZ), oxygen resistant effusion cells (OREZ), organic molecules effusion (OME) and thermal cracker cells (TCC). Effusion cell based thermal evaporation includes a crucible with a thermocouple temperature sensor heated by a resistive crucible heater. Radiation heat transfer from the crucible to the thermocouple temperature sensor produces a thermocouple temperature that is consistent and reproducible for a given crucible temperature. The crucible temperature stability is estimated from the measured sensitivity of the evaporation rate to temperature, and the observed variations in the evaporation rate for a fixed thermocouple temperature.

In one or more embodiments, depositing a layer comprises one or more of spin-coating, thermal evaporation, chemical vapor deposition (CVD), physical vapor deposition (PVD), spray-coating (including ultrasonic spray coating, vibration assisted sequential spray coating, air-brush coating), inkjet printing, slot-die coating, blade coating, close space sublimation or drop-casting. As used herein, the term “drop-cast” or “drop-casting” refers to a coating procedure where large droplets with controlled sizes and momentum are released that spread and wet the surface upon impact.

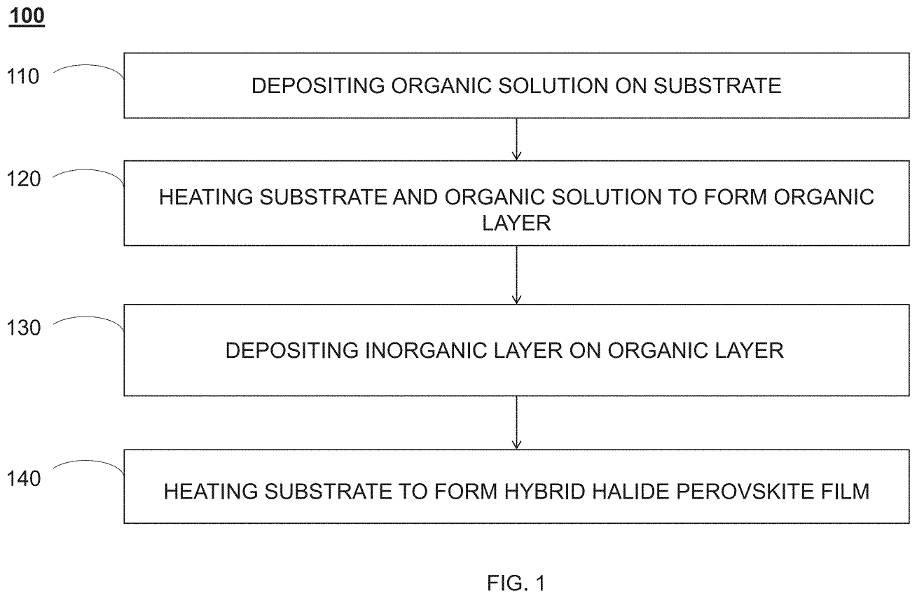

Referring now to FIG. 1, a flow diagram of a method of forming a film is shown. The method 100 comprises at operation 110 depositing an organic solution on a substrate, at operation 120 heating the substrate and the organic solution to form an organic layer on the substrate, at operation 130 depositing an inorganic layer on the organic layer, and at operation 140 heating the substrate having the inorganic layer thereon to form a hybrid halide perovskite film. As used herein, “perovskite film” refers to a film comprising a class of compounds which have the same type of crystal structure as CaTiO₃ (^{XII}A^{2+VI}B⁴⁺X²⁻₃), known as the perovskite structure.

Some embodiments of the disclosure provide depositing the organic portion and depositing the inorganic portion of a hybrid halide perovskite film separately. In some embodiments, an organic portion in solvent is deposited by spin-coating and an inorganic portion is deposited by thermal evaporation. The film may then be heated to induce crystallization. Heating the film permits the organic portion and the inorganic portion to combine and form a homogenous single phase.

In one or more embodiments, the method 100 comprises forming a hybrid halide perovskite film comprising a CH[NH₂]₂⁺MX₃ compound, where M is selected from the group consisting of Sn, Pb, Bi, Mg and Mn, and where X is selected from the group consisting of I, Br and Cl. In one or more embodiments, the method 100 comprises at operation 110 depositing a CH[NH₂]₂X solution on a substrate, at operation 120 heating the substrate and the CH[NH₂]₂X solution to form a CH[NH₂]₂X layer on the substrate, at operation 130 depositing an MX₂ layer on the CH[NH₂]₂X layer, and at operation 140 heating the substrate having the CH[NH₂]₂X layer and the MX₂ layer thereon to form the hybrid halide perovskite film comprising a CH[NH₂]₂⁺MX₃ compound.

In one or more embodiments, depositing a CH[NH₂]₂X solution on the substrate comprises performing a spin-coating process. In one or more embodiments, performing the spin-coating process comprises spin-coating the CH[NH₂]₂X solution on the substrate in a range from about 100 rpm to about 6000 rpm, in a range from about 2000 rpm to about 5000 rpm or in a range from about 4000 rpm to about 4500 rpm. In one or more embodiments, the spin-coating process includes CH[NH₂]₂X in an isopropyl alcohol solution. In one or more embodiments, the spin-coating process includes CH[NH₂]₂X in a methanol solution. In one or more embodiments, the spin-coating process includes CH[NH₂]₂X in an acetone solution.

In one or more embodiments, heating the substrate and the CH[NH₂]₂X solution to form a CH[NH₂]₂X layer on the substrate includes heating the substrate to a temperature in a range from 60° C. to about 100° C., in a range from about 65° C. to about 80° C., or in a range from about 70° C. to about 75° C.

In one or more embodiments, depositing an MX₂ layer on the CH[NH₂]₂X layer comprises performing a thermal evaporation process. In one or more embodiments, the thermal evaporation process is performed in a vacuum chamber. In one or more embodiments, the thermal evaporation process includes an evaporation rate which is adjusted by controlling an evaporation temperature in the vacuum chamber.

In one or more embodiments, performing the thermal evaporation process includes adjusting a pressure in the vacuum chamber to a range from about 9×10⁻⁶ mbar to about 1×10⁻⁶ mbar, to a range from about 5×10⁻⁶ mbar to about 7×10⁻⁶ mbar, or to a range from about 2×10⁻⁶ mbar to about 4×10⁻⁶ mbar.

In one or more embodiments, the film includes a pre-determined thickness. In one or more embodiments, the method 100 optionally includes discarding the film if the film is formed having a thickness that is not the pre-determined thickness.

In one or more embodiments, heating the substrate having the CH[NH₂]₂X layer and the MX₂ layer thereon to form the film comprising a CH[NH₂]₂⁺MX₃ compound includes heating the substrate to a temperature in a range from 60° C. to about 100° C., in a range from about 65° C. to about 80° C., or in a range from about 70° C. to about 75° C.

In one or more embodiments, the method 100 comprises depositing a formamidinium halide (FAX) solution, where X is selected from the group consisting of I, Br and Cl on a substrate, heating the substrate and the FAX solution to form a FAX layer on the substrate, depositing an MX₂ layer where M is selected from the group consisting of Sn, Pb, Bi, Mg and Mn, and X is selected from the group consisting of I, Br and Cl on the FAX layer, and heating the substrate having the FAX layer and the MX₂ layer thereon to form a hybrid halide perovskite film comprising a FAMX₃ compound.

In one or more embodiments, depositing a FAX solution on the substrate comprises performing a spin-coating process. In one or more embodiments, performing the spin-coating process comprises spin-coating the FAX solution on the substrate in a range from about 100 rpm to about 6000 rpm, in a range from about 2000 rpm to about 5000 rpm or in a range from about 4000 rpm to about 4500 rpm. In one or more embodiments, the spin-coating process includes FAX in a dimethylformamide (DMF) organic solution. In one or more embodiments, the spin-coating process includes FAX in an acetone solution.

In one or more embodiments, the FAX solution comprises FAI and the FAX layer comprises FAI. In one or more embodiments, heating the substrate and the FAI solution to form the FAI layer on the substrate includes heating the substrate to a temperature in a range from about 60° C. to about 100° C., in a range from about 65° C. to about 80° C., or in a range from about 70° C. to about 75° C.

In one or more embodiments, the FAX solution comprises FABr and the FAX layer comprises FABr. In one or more embodiments, heating the substrate and the FABr solution to form the FABr layer on the substrate includes heating the substrate to a temperature in a range from about 70° C. to about 110° C., in a range from about 70° C. to about 85° C., or in a range from about 75° C. to about 85° C.

In one or more embodiments, depositing the MX₂ layer on the FAX layer comprises performing a thermal evaporation process. In one or more embodiments, the thermal evaporation process is performed in a vacuum chamber. In one or more embodiments, the thermal evaporation process includes an evaporation rate which is adjusted by controlling an evaporation temperature in the vacuum chamber.

In one or more embodiments, performing the thermal evaporation process includes adjusting a pressure in the vacuum chamber to a range from about 9×10⁻⁶ mbar to about 1×10⁻⁶ mbar, to a range from about 5×10⁻⁶ mbar to about 7×10⁻⁶ mbar, or to a range from about 2×10⁻⁶ mbar to about 4×10⁻⁶ mbar.

In one or more embodiments, the film includes a pre-determined thickness. In one or more embodiments, the method 100 optionally includes discarding the film if the film is formed having a thickness that is not the pre-determined thickness.

In one or more embodiments, heating the substrate having the FAX layer and the MX₂ layer thereon comprises heating the substrate to a temperature in a range from about 60° C. to about 100° C., from about 65° C. to about 80° C. or from about 70° C. to about 75° C. to form the hybrid halide perovskite film comprising a FAMX₃ compound.

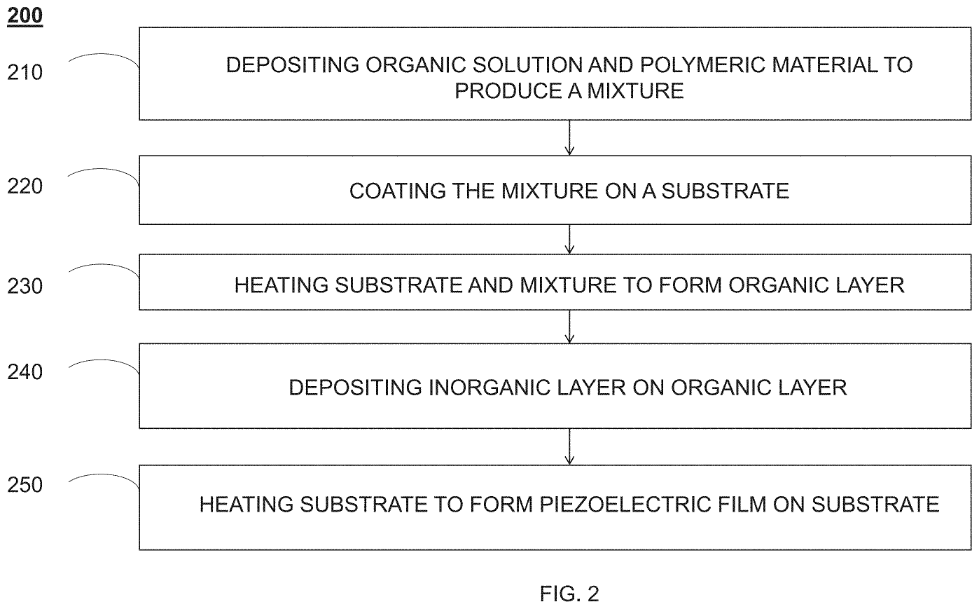

Referring now to FIG. 2, a flow diagram of a method 200 of forming a piezoelectric device is shown. The method 200 comprises at operation 210 depositing an organic solution and a polymeric material to produce a mixture, at operation 220 coating the mixture on a substrate, at operation 230 heating the substrate and the mixture to form an organic layer on the substrate, at operation 240 depositing an inorganic layer on the organic layer, and at operation 250 heating the substrate having the organic layer and the inorganic layer thereon to produce a piezoelectric film disposed on the substrate.

In one or more embodiments, the method 200 comprises forming a piezoelectric film comprising a CH[NH₂]₂⁺MX₃ compound, where M is selected from the group consisting of Sn, Pb, Bi, Mg and Mn, and where X is selected from the group consisting of I, Br and Cl. In one or more embodiments, the method 200 comprises depositing a CH[NH₂]₂X solution and polymeric material to produce a mixture, coating the mixture on a substrate, heating the substrate and the CH[NH₂]₂X solution to form a CH[NH₂]₂X layer on the substrate, depositing an MX₂ layer on the CH[NH₂]₂X layer, and heating the substrate having the CH[NH₂]₂X layer and the MX₂ layer thereon to produce a piezoelectric film comprising a CH[NH₂]₂⁺MX₃ compound disposed on the substrate.

In one or more embodiments, depositing a CH[NH₂]₂X solution and a polymeric material to produce a mixture includes CH[NH₂]₂X in an isopropyl alcohol solution. In one or more embodiments, the spin-coating process includes CH[NH₂]₂X in a methanol solution. In one or more embodiments, the spin-coating process includes CH[NH₂]₂X in an acetone solution. In one or more embodiments, polymeric materials include polyvinylidene difluoride (PVDF), polymethyl methacrylate (PMMA), Nylon 11 (or polyamide 11) and polystyrene.

In one or more embodiments, coating the mixture on the substrate comprises performing a spin-coating process. In one or more embodiments, performing the spin-coating process comprises spin-coating the CH[NH₂]₂X solution on the substrate in a range from about 100 rpm to about 6000 rpm, in a range from about 2000 rpm to about 5000 rpm or in a range from about 4000 rpm to about 4500 rpm.

In one or more embodiments, heating the substrate and the CH[NH₂]₂X solution to form a CH[NH₂]₂X layer on the substrate includes heating the substrate to a temperature in a range from 60° C. to about 100° C., in a range from about 65° C. to about 80° C., or in a range from about 70° C. to about 75° C.

In one or more embodiments, depositing an MX₂ layer on the CH[NH₂]₂X layer comprises performing a thermal evaporation process. In one or more embodiments, the thermal evaporation process is performed in a vacuum chamber. In one or more embodiments, the thermal evaporation process includes an evaporation rate which is adjusted by controlling an evaporation temperature in the vacuum chamber.

In one or more embodiments, performing the thermal evaporation process includes adjusting a pressure in the vacuum chamber to a range from about 9×10⁻⁶ mbar to about 1×10⁻⁶ mbar, to a range from about 5×10⁻⁶ mbar to about 7×10⁻⁶ mbar, or to a range from about 2×10⁻⁶ mbar to about 4×10⁻⁶ mbar.

In one or more embodiments, the piezoelectric film includes a pre-determined thickness. In one or more embodiments, the method 200 optionally includes discarding the piezoelectric film if the piezoelectric film is formed having a thickness that is not the pre-determined thickness.

In one or more embodiments, heating the substrate having the CH[NH₂]₂X layer and the MX₂ layer thereon to form the film comprising a CH[NH₂]₂⁺MX₃ compound includes heating the substrate to a temperature in a range from 60° C. to about 100° C., in a range from about 65° C. to about 80° C., or in a range from about 70° C. to about 75° C.

In one or more embodiments, the method 200 comprises depositing a formamidinium halide (FAX) solution, where X is selected from the group consisting of I, Br and Cl and a polymeric material to produce a mixture, coating the mixture on a substrate, heating the substrate and the mixture to form a FAX layer on the substrate, depositing an MX₂ layer, where M is selected from the group consisting of Sn, Pb, Bi, Mg and Mn, and X is selected from the group consisting of I, Br and Cl on the FAX layer, and heating the substrate having the FAX layer and the MX₂ layer thereon to produce a piezoelectric film comprising a FAMX₃ compound disposed on the substrate.

In one or more embodiments, depositing a FAX solution and a polymeric material to produce a mixture comprises FAX in a dimethylformamide (DMF) organic solution. In one or more embodiments, the spin-coating process includes FAX in an acetone solution. In one or more embodiments, the polymeric material includes PVDF, PMMA, Nylon 11 and polystyrene.

In one or more embodiments, coating the mixture on the substrate comprises performing a spin-coating process. In one or more embodiments, performing the spin-coating process comprises spin-coating the FAX solution on the substrate in a range from about 100 rpm to about 6000 rpm, in a range from about 2000 rpm to about 5000 rpm or in a range from about 4000 rpm to about 4500 rpm.

In one or more embodiments, the FAX solution comprises FAI. In one or more embodiments, heating the substrate and the mixture to form the FAX layer comprising FAI on the substrate includes heating the substrate to a temperature in a range from about 60° C. to about 100° C., in a range from about 65° C. to about 80° C., or in a range from about 70° C. to about 75° C.

In one or more embodiments, the FAX solution comprises FABr. In one or more embodiments, heating the substrate and the mixture to form the FAX layer comprising FABr on the substrate includes heating the substrate to a temperature in a range from about 70° C. to about 110° C., in a range from about 70° C. to about 85° C., or in a range from about 75° C. to about 85° C.

In one or more embodiments, depositing the MX₂ layer on the FAX layer comprises performing a thermal evaporation process. In one or more embodiments, the thermal evaporation process is performed in a vacuum chamber. In one or more embodiments, the thermal evaporation process includes an evaporation rate which is adjusted by controlling an evaporation temperature in the vacuum chamber.

In one or more embodiments, performing the thermal evaporation process includes adjusting a pressure in the vacuum chamber to a range from about 9×10⁻⁶ mbar to about 1×10⁻⁶ mbar, to a range from about 5×10⁻⁶ mbar to about 7×10⁻⁶ mbar, or to a range from about 2×10⁻⁶ mbar to about 4×10⁻⁶ mbar.

In one or more embodiments, the piezoelectric film includes a pre-determined thickness. In one or more embodiments, the method 200 optionally includes discarding the piezoelectric film if the piezoelectric film is formed having a thickness that is not the pre-determined thickness.

In one or more embodiments, heating the substrate having the FAX layer and the MX₂ layer thereon to produce the piezoelectric film comprising a FAMX₃ compound comprises heating the substrate to a temperature in a range from about 60° C. to about 100° C., from about 65° C. to about 80° C. or from about 70° C. to about 75° C.

In one or more embodiments, the piezoelectric film comprises a piezoelectric composite material comprising the FAMX₃ compound and the polymeric material uniformly distributed throughout.

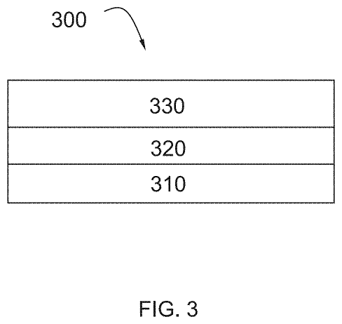

Referring now to FIG. 3, a schematic cross-sectional view of a hybrid halide perovskite film 300 is shown. In one or more embodiments, the hybrid halide perovskite film 300 comprises an organic solution on a substrate 310, the substrate 310 and the organic solution heated to form an organic layer 320 on the substrate 310. In one or more embodiments, the hybrid halide perovskite film 300 comprises an inorganic layer 330 on the organic layer 320. In one or more embodiments, heating the substrate 310 having the inorganic layer 330 thereon forms the hybrid halide perovskite film 300.

In one or more embodiments, the hybrid halide perovskite film 300 comprises CH[NH₂]₂⁺MX₃, where M is selected from the group consisting of Sn, Pb, Bi, Mg and Mn, and where X is selected from the group consisting of I, Br and Cl. In one or more embodiments, the hybrid halide perovskite film 300 comprises a CH[NH₂]₂X solution on a substrate 310, the substrate 310 and the CH[NH₂]₂X solution heated to form a CH[NH₂]₂X layer 320 on the substrate 310. In one or more embodiments, the hybrid halide perovskite film 300 comprises an MX₂ layer 330 on the CH[NH₂]₂X layer 320. In one or more embodiments, heating the substrate 310 having the CH[NH₂]₂X layer 320 and the MX₂ layer 330 thereon forms the hybrid halide perovskite film 300 comprising a CH[NH₂]₂⁺MX₃ compound.

Referring still to FIG. 3, in one or more embodiments, the hybrid halide perovskite film 300 comprises FAMX₃, where FA is formamidinium, M is selected from the group consisting of Sn, Pb, Bi, Mg and Mn, and X is selected from the group consisting of I, Br and Cl. In one or more embodiments, the hybrid halide perovskite film 300 comprises a FAX solution on a substrate 310, the substrate 310 and the FAX solution heated to form a FAX layer 320 on the substrate 310. In one or more embodiments, the hybrid halide perovskite film 300 comprises an MX₂ layer 330 on the FAX layer 320. In one or more embodiments, heating the substrate 310 having the FAX layer 320 and the MX₂ layer 330 thereon forms the hybrid halide perovskite film 300 comprising a FAMX₃ compound.

In one or more embodiments, the hybrid halide perovskite film 300 comprises a FAX solution on a substrate 310, the substrate 310 and the FAX solution heated to form a FAX layer 320 on the substrate 310. In one or more embodiments, the FAX solution comprises FAI and the FAX layer 320 comprises FAI. In one or more embodiments, the hybrid halide perovskite film 300 comprises a FAI layer 320 on the substrate 310. In one or more embodiments, the hybrid halide perovskite film 300 comprises an MI₂ layer 330 on the FAI layer 320. In one or more embodiments, heating the substrate 310 having the FAI layer 320 and the MI₂ layer 330 thereon forms the hybrid halide perovskite film 300 comprising a FAMI₃ compound.

In one or more embodiments, the hybrid halide perovskite film 300 comprises a FAX solution on a substrate 310, the substrate 310 and the FAX solution heated to form a FAX layer 320 on the substrate 310. In one or more embodiments, the FAX solution comprises FABr and the FAX layer 320 comprises FABr. In one or more embodiments, the hybrid halide perovskite film 300 comprises a FABr layer 320 on the substrate 310. In one or more embodiments, the hybrid halide perovskite film 300 comprises an MBr₂ layer 330 on the FABr layer 320. In one or more embodiments, heating the substrate 310 having the FABr layer 320 and the MBr₂ layer 330 thereon forms the hybrid halide perovskite film 300 comprising a FAMBr₃ compound.

In one or more embodiments, the hybrid halide perovskite film 300 comprises a FAX solution on a substrate 310, the substrate 310 and the FAX solution heated to form a FAX layer 320 on the substrate 310. In one or more embodiments, the FAX solution comprises FACl and the FAX layer 320 comprises FACl. In one or more embodiments, the hybrid halide perovskite film 300 comprises a FACl layer 320 on the substrate 310. In one or more embodiments, the hybrid halide perovskite film 300 comprises an MCl₂ layer 330 on the FACl layer 320. In one or more embodiments, heating the substrate 310 having the FACl layer 320 and the MCl₂ layer 330 thereon forms the hybrid halide perovskite film 300 comprising a FAMCl₃ compound.

In one or more embodiments, the hybrid perovskite film 300 is a piezoelectric film configured for use in a piezoelectric device.

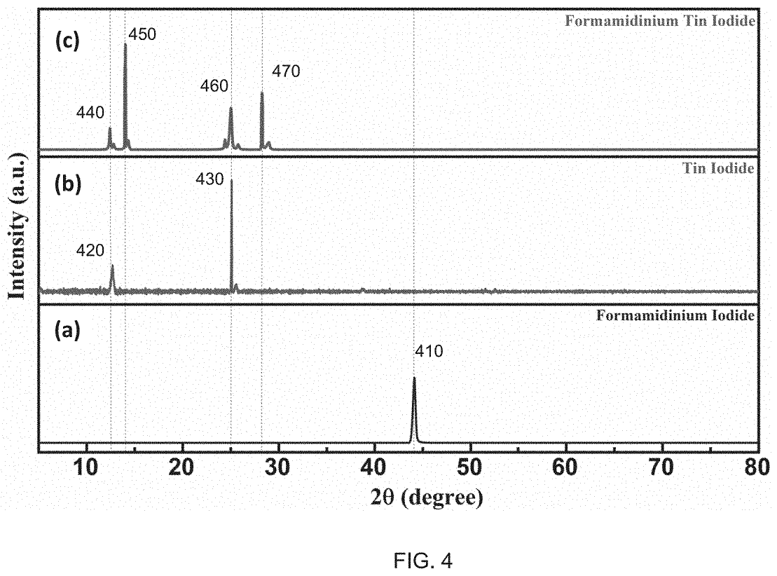

FIG. 4 illustrates an x-ray diffraction (XRD) reading of an exemplary embodiment of a formamidinium tin iodide (FASnI₃) film. The XRD reading illustrates a vertical axis and a horizontal axis. The vertical axis represents intensity based on counts per second, and the horizontal axis represents a 26 scale in degrees.

Referring again to FIG. 4, XRD reading (a) shows a single formamidinium iodide (FAI) peak 410 at about 44 degrees for a spin-coated FAI film only. XRD reading (b) shows a first tin iodide (SnI₂) peak 420 at about 12 degrees and a sharp second SnI₂ peak 430 at about 25 degrees for a thermally evaporated SnI₂ film only. The first tin iodide (SnI₂) peak 420 and the sharp second SnI₂ peak 430 demonstrate amorphous phase of the tin iodide. XRD reading (c) shows peaks for FASnI₃, including a low-intensity peak 440 at about 12 degrees, a high intensity peak 450 at about 14 degrees, a medium intensity peak 460 at about 25 degrees and a peak 470 at about 28 degrees. The XRD reading (c) shows peaks for a FASnI₃ film formed by spin-coating a FAI layer on the substrate, performing an annealing process, then thermally evaporating the SnI₂ layer on the FAI layer.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

What is claimed is:

1. A method of forming a film, the method comprising:
depositing a CH[NH₂]₂X solution on a substrate, where X is selected from the group consisting of I, Br and Cl;
heating the substrate and the CH[NH₂]₂X solution to form a CH[NH₂]₂X layer on the substrate;
depositing an MX₂ layer, where M is selected from the group consisting of Sn, Pb, Bi, Mg and Mn on the CH[NH₂]₂X layer; and
heating the substrate having the CH[NH₂]₂X layer and the MX₂ layer thereon to form a hybrid halide perovskite film comprising a CH[NH₂]₂⁺MX₃ compound.

2. The method of claim 1, wherein depositing the CH[NH₂]₂X solution on the substrate comprises performing a spin-coating process.

3. The method of claim 2, wherein performing the spin-coating process comprises spin-coating the CH[NH₂]₂X solution on the substrate in a range from about 100 rpm to about 6000 rpm, in a range from about 2000 rpm to about 5000 rpm or in a range from about 4000 rpm to about 4500 rpm.

4. The method of claim 1, wherein depositing the MX₂ layer on the CH[NH₂]₂X layer comprises performing a thermal evaporation process.

5. A method of forming a film, the method comprising:
depositing a formamidinium halide (FAX) solution, where X is selected from the group consisting of I, Br and Cl on a substrate;
heating the substrate and the FAX solution to form a FAX layer on the substrate;
depositing an MX₂ layer, where M is selected from the group consisting of Sn, Pb, Bi, Mg and Mn, and X is selected from the group consisting of I, Br and Cl on the FAX layer; and
heating the substrate having the FAX layer and the MX₂ layer thereon to form a hybrid halide perovskite film comprising a FAMX₃ compound.

6. The method of claim 5, wherein depositing the FAX solution on the substrate comprises performing a spin-coating process.

7. The method of claim 6, wherein performing the spin-coating process comprises spin-coating the FAX solution on the substrate in a range from about 100 rpm to about 6000 rpm, in a range from about 2000 rpm to about 5000 rpm or in a range from about 4000 rpm to about 4500 rpm.

8. The method of claim 5, wherein heating the substrate and the FAX solution comprising FAI to form the FAX layer comprising FAI on the substrate includes heating the substrate to a temperature in a range from about 60° C. to about 100° C., in a range from about 65° C. to about 80° C., or in a range from about 70° C. to about 75° C.

9. The method of claim 5, wherein heating the substrate and the FAX solution comprising FABr to form the FAX layer comprising FABr on the substrate includes heating the substrate to a temperature in a range from about 70° C. to about 110° C., in a range from about 70° C. to about 85° C., or in a range from about 75° C. to about 85° C.

10. The method of claim 5, wherein depositing the MX₂ layer on the FAX layer comprises performing a thermal evaporation process.

11. The method of claim 10, wherein the thermal evaporation process is performed in a vacuum chamber.

12. The method of claim 11, wherein the thermal evaporation process includes an evaporation rate which is adjusted by controlling an evaporation temperature in the vacuum chamber.

13. The method of claim 11, wherein performing the thermal evaporation process includes adjusting a pressure in the vacuum chamber to a range from about 9×10⁻⁶ mbar to about 1×10⁻⁶ mbar.

14. The method of claim 11, wherein performing the thermal evaporation process includes adjusting a pressure in the vacuum chamber to a range from about 5×10⁻⁶ mbar to about 7×10⁻⁶ mbar.

15. The method of claim 11, wherein performing the thermal evaporation process includes adjusting a pressure in the vacuum chamber to a range from about 2×10⁻⁶ mbar to about 4×10⁻⁶ mbar.

16. The method of claim 5, wherein heating the substrate having the FAX layer and the MX₂ layer thereon comprises heating the substrate to a temperature in a range from about 60° C. to about 100° C. to form the hybrid halide perovskite film comprising a FAMX₃ compound.

17. The method of claim 5, wherein heating the substrate having the FAX layer and the MX₂ layer thereon comprises heating the substrate to a temperature in a range from about 65° C. to about 80° C. to form the hybrid halide perovskite film comprising a FAMX₃ compound.

18. The method of claim 5, wherein heating the substrate having the FAX layer and the MX₂ layer thereon comprises heating the substrate to a temperature in a range from about 70° C. to about 75° C. to form the hybrid halide perovskite film comprising a FAMX₃ compound.

19. A method of forming a piezoelectric device, the method comprising:
depositing a formamidinium halide (FAX) solution, where X is selected from the group consisting of I, Br and Cl, and a polymeric material to produce a mixture;
coating the mixture on a substrate;
heating the substrate and the mixture to form a FAX layer on the substrate;
depositing an MX₂ layer where M is selected from the group consisting of Sn, Pb, Bi, Mg and Mn, and X is selected from the group consisting of I, Br and Cl, on the FAX layer; and
heating the substrate having the FAX layer and the MX₂ layer thereon to produce a piezoelectric film comprising a FAMX₃ compound disposed on the substrate.

20. The method of claim 19, wherein the piezoelectric film comprises a piezoelectric composite material comprising the FAMX₃ compound and the polymeric material uniformly distributed throughout.
